(19) United States
(12) Patent Application Publication
(10) Pub. No.: US 2005/0253234 A1
(43) Pub. Date: Nov. 17, 2005

(54) Semiconductor package and method of fabricating the same

(76) Inventors: Dong-Han Kim, Gyeonggi-do (KR); Si-Hoon Lee, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/115,861

(22) Filed: Apr. 26, 2005

(30) Foreign Application Priority Data
May 12, 2004 (KR) 2004-33377

(51) Int. Cl. H01L 23/495

(52) U.S. Cl. 257/678

(57) ABSTRACT

A TAB type package on which a semiconductor chip is mounted and a method of manufacturing the same. The semiconductor package includes a plurality of inner leads to be connected to the semiconductor chip and formed on a base film, and a plurality of reinforcing leads connected to four edges of short sides of the semiconductor chip. The reinforcing leads help prevent deformation due to heat of the base film. Heat-induced stress is distributed to avoid a disconnection.

### BACKGROUND OF THE INVENTION

This application claims the priority of Korean Patent Application No. 2004-33377, filed on May 12, 2004, in the Korean Intellectual Property Office, the disclosure of which is incorporated herein in its entirety by reference.

1. Field of the Invention

The invention relates to a semiconductor package and a method of fabricating the same, and more particularly, to a semiconductor package, e.g., tape automated bonding (TAB) type package on which a semiconductor chip is mounted and a method of fabricating the same.

2. Description of the Related Art

Generally, TAB is a technique of electrically connecting bumps formed on a semiconductor chip and each of the inner leads patterned on a TAB tape. The use of a TAB type package is increasing due to the trend toward slim packaging, fine pitch, and multi-pining.

TAB has several advantages over the conventional wire bonding. First, it is advantageous to form a multi-pin package and fine pitches since small bonding bumps can be formed on a chip. Also, all bonding work can be done simultaneously, and the bonding parts have a strong bonding force. Furthermore, in the case of a multi-chip module, manufacturing a slim package is possible by reducing the distance between the semiconductor chips.

A TAB type package is one of two types: a tape carrier package (TCP) and a chip-on-film (COF). The TCP has a device hole, for mounting a semiconductor chip, in a base film. But the COF is formed via a packaging method on the base film without a device hole.

Here, the TCP as an example will be described.

FIG. 1 is a plan view illustrating a conventional TCP. Referring to FIG. 1, a device hole 12, which is a region for mounting a semiconductor chip 14, is formed in a base film 10. A plurality of inner leads 16, to be connected with the semiconductor chip 14, are patterned on the base film 10. An end of the inner leads 16 facing the device hole 12 are to bonding bumps 18 formed on the semiconductor chip 14.

The inner leads 16 and the bonding bumps 18 are all conductive materials. Connecting the inner leads 16 and the bonding bumps 18 is performed by bonding at a temperature of about 500° C. under a high pressure. The applied heat is transferred to the base film 10 through the inner leads 16. The transferred heat expands the base film 10 which later contracts when the heat transferring is terminated.

FIG. 2 is a plan view for describing problems of the conventional TCP of FIG. 1.

Referring to FIG. 2, heat applied to the semiconductor chip 14 acts upon the base film 10 according to the length of an edge of the semiconductor chip 14. Heat that dissipates along the X axis slightly affects the base film 10 since it is transferred easily to the outside. However, heat that dissipates along the Y axis significantly affects the base film 10 since the heat is not easily transferred to the outside. Accordingly, a width of the base film 10 expanding along the Y axis is relatively greater than a width of the base film 10 expanding along the X axis. Meanwhile, the expansion of the base film 10 is the main cause of deformation by heat since the semiconductor chip 14 expands very little by heat.

When the base film 10 expands along the Y axis, the inner leads 16 arranged along the X axis deform. That is, the inner leads 16 between the base film 10 and the bonding bumps 18 deform along the Y axis. In the worst case, some of the inner leads 16 are disconnected as shown in FIG. 2. Also, the inner leads 16 arranged along the Y axis may disconnect due to the stress generated by the expansion caused by the thermal deformation of the base film 10. The inner leads 16 of both ends can be disconnected since the inner leads 16 located outermost are subjected to greater stress than the inner leads 16 in the central part. When the transfer of heat is terminated, the base film 10 contracts, and in this case also, the deformation along the Y axis is greater than that along the X axis. Therefore, the deformation or disconnection of the inner leads 16 can occur when the base film 10 contracts or expands.

### SUMMARY OF THE INVENTION

According to an aspect of the invention, there is provided a semiconductor package on which a semiconductor chip is mounted, comprising: a base film, a plurality of inner leads to be connected to the semiconductor chip formed on the base film, and a plurality of reinforcing leads substantially vertically connected to four edges of short sides of the semiconductor chip.

The numbers of the reinforcing leads formed on each of the four corners of the semiconductor chip may be equal to one another and at least two. The reinforcing leads formed on the four corners of the semiconductor chip have substantially identical shapes.

The reinforcing leads can be bonded to the edges of the base film using a polymer adhesive and may have a length long enough to maintain a bonding force with the base film.

A width of the reinforcing leads may be equal to or greater than the width of the inner leads.

The reinforcing leads can be formed of a bar shaped conductive material, and a circumference of the reinforcing leads can be coated with tin or gold.

The TAB type package can further comprise bonding bumps between the reinforcing and inner leads and the semiconductor chip. Also, distances between the bonding bumps may be equal to one another.

The TAB type package can further comprise strengthening leads that strengthens the bonding force of the reinforcing leads in a direction substantially vertical to the reinforcing leads.

A device hole in which the semiconductor chip is mounted can be formed in the base film.

According to another aspect of the invention, there is provided a method of manufacturing a semiconductor package, comprising: forming reinforcing leads on a base film, and substantially vertically connecting a portion of the reinforcing leads to four corners of short sides of a semiconductor chip.

The forming of the reinforcing leads comprises: coating a conductive material layer on the base film, forming a photoresist pattern that defines the reinforcing leads on the conductive material layer, and forming the reinforcing leads by etching the conductive material layer using the photoresist pattern as an etch mask.

The forming of the reinforcing leads comprises: forming a device hole in which the semiconductor chip is mounted in the base film, coating a polymer adhesive layer on the base film, bonding a conductive material plate to the polymer adhesive layer, forming a photoresist pattern that defines the reinforcing leads on the polymer adhesive layer, and forming the reinforcing leads by etching the conductive material plate using the photoresist pattern as an etch mask.

The connecting of a portion of the reinforcing leads comprises: forming bonding bumps on the corners of the semiconductor chip, placing a portion of the reinforcing leads on the bonding bumps, and applying heat at least greater than about 500° C. with a predetermined compression to the reinforcing leads in a substantially vertical direction to the reinforcing leads.

### BRIEF DESCRIPTION OF THE DRAWINGS

The above and other features and advantages of the present invention will become more apparent by describing in detail exemplary embodiments thereof with reference to the attached drawings in which:

FIG. 1 is a plan view illustrating a conventional TCP;

FIG. 2 is a plan view illustrating problems of the conventional TCP of FIG. 1;

FIG. 3 is a cross-sectional view illustrating a TCP according to an aspect of the present invention;

FIG. 4 is a plan view of FIG. 3;

FIGS. 5 and 6 are cross-sectional views taken along line V-V′ in FIG. 4 for explaining reinforcing leads and inner leads according to an embodiment of the present invention;

FIGS. 7 through 12 are cross-sectional views illustrating a method of manufacturing a TCP on which a semiconductor chip is mounted, according to another embodiment of the present invention;

FIG. 13 is a cross-sectional view illustrating a COF according to yet another embodiment of the present invention; and

FIG. 14 is a plan view of the COF in FIG. 13.

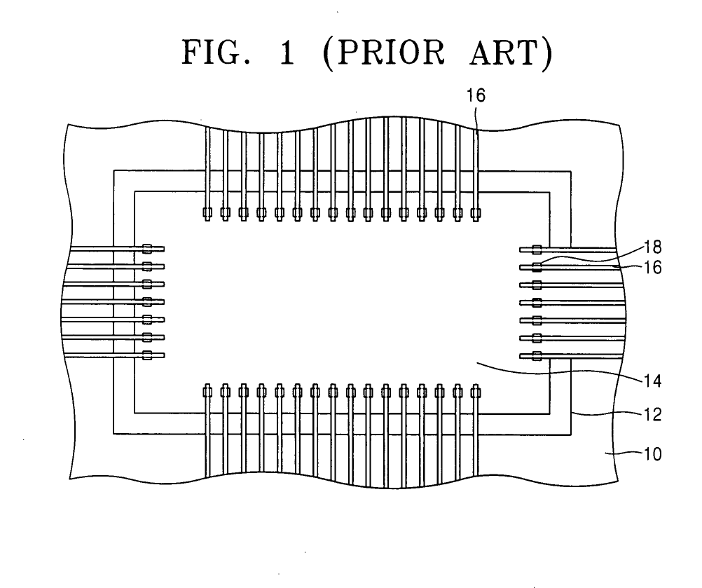

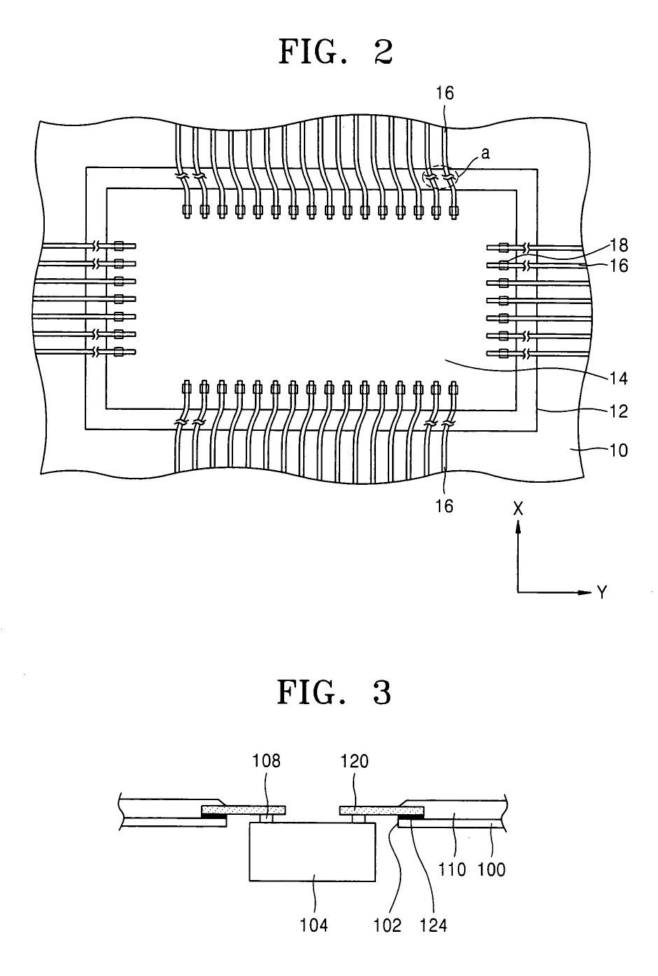

### DETAILED DESCRIPTION OF THE INVENTION

The invention will now be described more fully with reference to the accompanying drawings in which embodiments of the invention are shown.

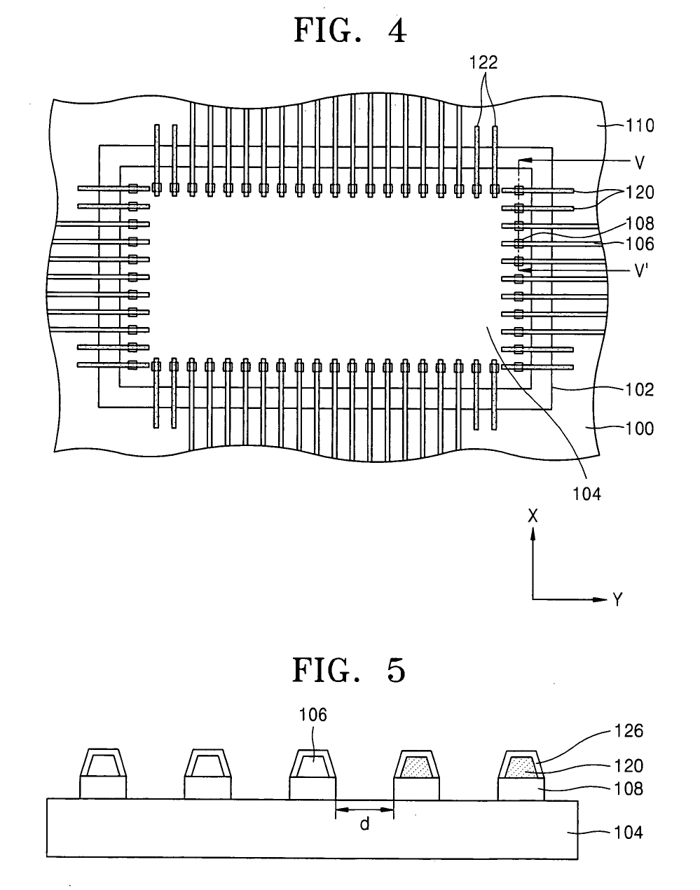

FIG. 3 is a cross-sectional view illustrating a TCP according to an embodiment of the invention, and FIG. 4 is a plan view of the TCP in FIG. 3.

Referring to FIGS. 3 and 4, a device hole 102, which is a region for mounting a semiconductor chip 104, is formed in a base film 100. A plurality of inner leads 106 connected to the semiconductor chip 104 are patterned on the base film 100. The end of each of the inner leads 106 facing the device hole 102 is bonded to bonding bumps 108 formed on the semiconductor chip 104. A solder resist layer 110 is on the film 100, to be explained later.

The semiconductor chip 104 is generally shaped as a hexahedron (block-shape) having a rectangular cross-section. The rectangular cross-section can have a short side along the X axis and a long side along the Y axis, the X-Y axes being defined in FIG. 4. A plurality of reinforcing leads 120 are formed substantially vertically to the short sides of four corners of the semiconductor chip 104, that is, parallel to the Y axis. Furthermore, the semiconductor chip 104 can include strengthening leads 122 for strengthening a bonding force of the reinforcing leads 120.

The purpose of forming the reinforcing leads 120 on the four corners of the semiconductor chip 104 is to obtain a balance of resistance forces to prevent thermal deformation. Here, the resistance force is a force opposing a stress caused by thermal expansion and preventing the base film 100 from thermal deformation. If one of the four corners does not have the reinforcing leads 120, a proper balance of the resistance forces can not be achieved, and thus the base film 100 is being deformed. For balancing the resistance forces in the four corners, the reinforcing leads 120 can be formed in equal numbers and to have a substantially identical shape. The strengthening leads 122 can also be formed in the four corners, with the same numbers and a substantially identical shape, in an orthogonal direction to the reinforcing leads 120.

Meanwhile, stresses generated at the base film 100 by heat are distributed to all the reinforcing leads 120. That is, the stresses are concentrated on the reinforcing leads 120 and act slightly on the base film 100 between the reinforcing leads 120. If there is only one reinforcing lead 120, the reinforcing lead 120 may be easily disconnected since all stresses are concentrated on it. Therefore, preferably, there are more than two reinforcing leads 120. A width of the reinforcing leads 120 is preferably equal to or greater than the width of the inner leads 106 to secure a sufficient resistance force against the stresses generated by the thermal expansion.

The reinforcing leads 120 formed on edges of the base film 100 are bonded using a polymer adhesive layer 124. The reinforcing leads 120 may be long enough to maintain a bonding force with the base film 100. That is, as long as the reinforcing leads 120 can maintain the bonding force, they can be formed as close as possible to edges of the base film 100.

The bonding bumps 108 may be formed between the semiconductor chip 104 and the reinforcing leads 120 and the inner leads 106. The bonding bumps 108 connect the reinforcing leads 120 and the inner leads 106 to the semiconductor chip 104.

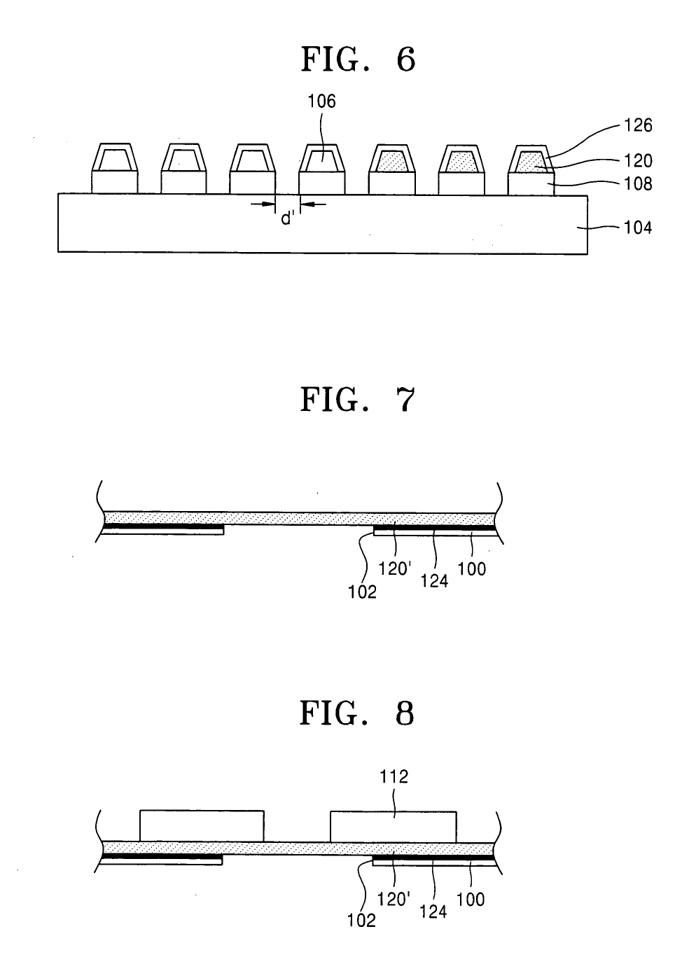

FIGS. 5 and 6 are cross-sectional views illustrating reinforcing leads and inner leads according to an embodiment of the invention.

Referring to FIGS. 5 and 6, the reinforcing leads 120 and the inner leads 106 are formed of a bar shaped conductive material such as copper. Outer circumferences 126 of the reinforcing leads 120 and the inner leads 106 can be coated with tin (Sn) or gold (Au). Bonding bumps 108 can be formed between the reinforcing leads 120 and inner leads 106 and the semiconductor chip 104. Distances d between the bonding bumps 108 are equal to each another. Therefore, the number of reinforcing leads 120 can be adjusted according to the distance of the bonding bumps 108 in a predetermined region. For example, as depicted in FIG. 6, if the distance between the bonding bumps 108 is reduced to d′, more reinforcing leads 120 can be formed.

FIGS. 7 through 12 are cross-sectional views illustrating a method of manufacturing a TCP on which a semiconductor chip is mounted according to an embodiment of the invention.

Referring to FIG. 7, the polymer adhesive layer 124 is coated on the base film 100 in which the device hole 102 for mounting the semiconductor chip 104 is formed. The base film 100 is an insulating polymer film. Generally, the base film 100 is a polyimide film. In some cases, a polyester film (not shown) can be attached on a base to protect the base film 100. Next, a conductive material plate 120′ in the form of a foil and made of a conductive material such as copper is bonded on the polymer adhesive layer 124. At this time, a thickness of the base film 100 is about 0.04 mm, and a thickness of the conductive material plate 120′ is about 0.008 mm.

Referring to FIG. 8, a photoresist pattern 112 that defines the reinforcing leads 120 thereunder is formed on the conductive material plate 120′. The photoresist pattern 112 can be formed by a conventional method.

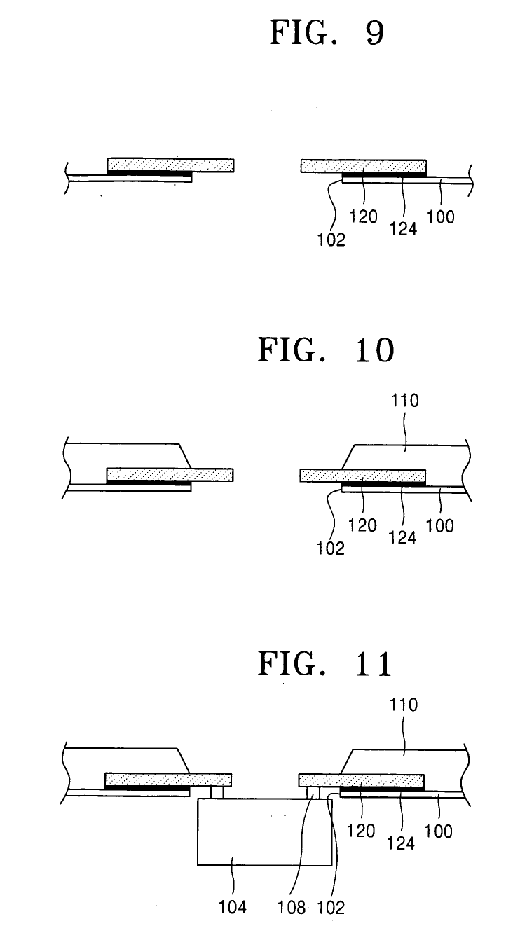

Referring to FIG. 9, the reinforcing leads 120 are formed by etching the conductive material plate 120′ to the shape of the photoresist pattern 112. At this time, an unwanted portion of the conductive material plate 120′, on which the photoresist pattern 112 is formed, is removed by spraying an etching solution. Next, the exposed polymer adhesive layer 124 is removed using a predetermined organic solvent.

Referring to FIG. 10, a solder resist layer 110 is coated on the entire surface of the base film 100 to protect the reinforcing leads 120. The solder resist layer 110 can be formed by coating a polymer resin such as epoxy.

Referring to FIG. 11, the bonding bumps 108 are formed on the corners of the semiconductor chip 104. The bonding bumps 108 are formed to electrically connect the semiconductor chip 104 to the inner leads 106 and may be formed of a conductive metal. Afterward, a portion of the reinforcing leads 120 is placed on the bonding bumps 108. At least about 500° C. of heat with a predetermined compression in a substantially vertical direction to the reinforcing leads 120 is applied to the semiconductor chip 104 on which the reinforcing leads 120 are placed. As a result, a portion of tin plating on the circumference 126 of the reinforcing leads 120 is melted and bonded to the bonding bumps 108. Also, a lower part of the reinforcing leads 120 is tightly bonded to the bonding bumps 108 by penetrating into the bonding bumps 108 by a pressure onto the reinforcing leads 120. The strengthening leads 122 and the reinforcing leads 120 are formed simultaneously. Also, the strengthening leads 122 are bonded to the bonding bumps 108 by the same method as the reinforcing leads 120.

According to the embodiment of the invention, the deformation of the base film 100 caused by heat can be prevented by forming the reinforcing leads 120 that connect the four corners of the semiconductor chip 104 and the base film 100. That is, a deformation or a disconnection of the inner leads 106 due to the deformation of the base film 100 can be prevented.

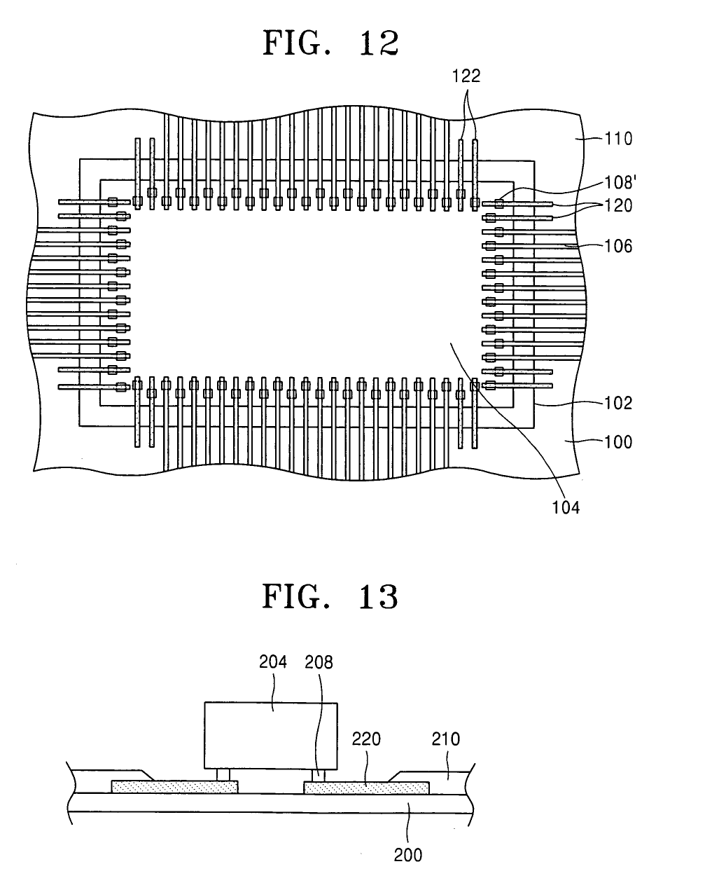

FIG. 12 is a plan view illustrating a different TCP according to this embodiment of the invention.

Referring to FIG. 12, bonding bumps 108′ are arranged in a zigzag pattern on the semiconductor chip 104 to allow an increased density of the inner leads 106. Accordingly, the bonding bumps 108′ under the reinforcing leads 120 and the strengthening leads 122 can also be arranged in zigzag.

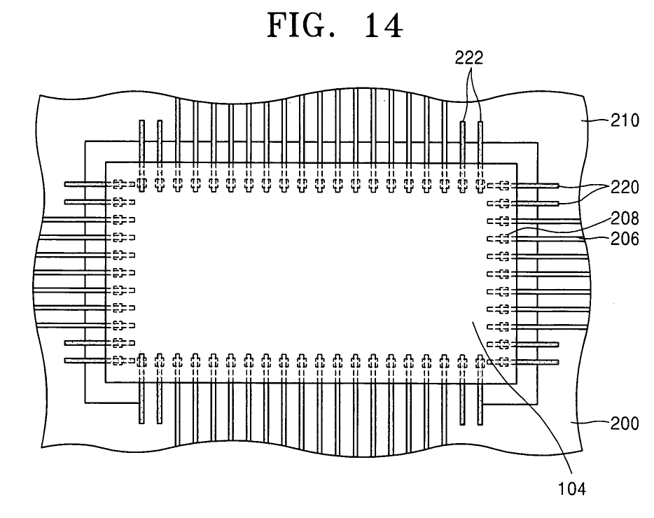

A COF according to another embodiment of the invention will now be described. FIG. 13 is a cross-sectional view illustrating a COF of the invention, and FIG. 14 is a plan view of the COF in FIG. 13.

Referring to FIGS. 13 and 14, a plurality of reinforcing leads 220 and strengthening leads 222 are patterned on a base film 200 as in the previous embodiment. A portion of the reinforcing leads 220 and the strengthening leads 222 facing the device hole 102 are melted and bonded to bonding bumps 208 formed on a semiconductor chip 204.

The reinforcing leads 220 and the strengthening leads 222 are formed so that first, a conductive material layer (not shown) is coated on the base film 200; a photoresist pattern (not shown) that defines the reinforcing leads 220 and the strengthening leads 222 is formed on the conductive material layer; and then the reinforcing leads 220 and the strengthening leads 222 are formed by etching the conductive material layer using the photoresist pattern as an etching mask.

Next, a portion of the reinforcing leads 220 and the strengthening leads 222 are placed on the bonding bumps 208 formed on the four corners of the semiconductor chip 204. Next, the reinforcing leads 220 and the strengthening leads 222 are bonded to the bonding bumps 208 by applying heat and pressure on an exposed surface of the semiconductor chip 204 or on a lower surface of the base film 200.

Here, a distance, number, length, and method of bonding to the bonding bumps 208 of the reinforcing leads 220 and the strengthening leads 222 may be the same as in the descriptions referring to FIGS. 7 through 12.

With an aspect of the present invention, deformation of the base film by heat can be prevented by forming reinforcing leads that connect the four edges of the semiconductor chip to the base film. That is, a deformation or disconnection of the inner leads due to the deformation of the base film can be prevented.

A disconnection of the inner leads can be prevented by forming a plurality of inner leads that distributes the stress applied to the reinforcing leads.

While the invention has been particularly shown and described with reference to exemplary embodiments thereof, it will be understood by those of ordinary skill in the art that various changes in form and details may be made therein without departing from the spirit and scope of the invention as defined by the following claims.

1. A semiconductor package for mounting a semiconductor chip thereon, the package comprising:
a base film;
a plurality of inner leads to be connected to the semiconductor chip overlying the base film;
a plurality of reinforcing leads substantially vertically connected to four corners of short sides of the semiconductor chip.

2. The semiconductor package of claim 1, wherein numbers of the reinforcing leads formed on each of the four corners of the semiconductor chip are equal to one another.

3. The semiconductor package of claim 1, wherein the plurality of reinforcing leads have a substantially identical shape.

4. The semiconductor package of claim 1, wherein there are formed at least two reinforcing leads on each of the four corners of the semiconductor chip.

5. The semiconductor package of claim 1, wherein the plurality of reinforcing leads are bonded to the base film using a polymer adhesive.

6. The semiconductor package of claim 1, wherein the plurality of reinforcing leads are long enough to maintain a bonding force with the base film.

7. The semiconductor package of claim 1, wherein a width of the plurality of reinforcing leads is substantially equal to or greater than the width of the inner leads.

8. The semiconductor package of claim 1, wherein the plurality of reinforcing leads are formed of a bar shaped conductive material.

9. The semiconductor package of claim 1, wherein a circumference of the reinforcing leads is coated with one of tin and gold.

10. The semiconductor package of claim 1 further comprising bonding bumps between the plurality of reinforcing and inner leads and the semiconductor chip.

11. The semiconductor package of claim 10, wherein distances between the bonding bumps are equal to one another.

12. The semiconductor package of claim 1, further comprising strengthening leads that strengthen the bonding force of the reinforcing leads in a direction perpendicular to the reinforcing leads.

13. The semiconductor package of claim 1, wherein a device hole is formed in the base film to mount the semiconductor chip.

14. A method of manufacturing a semiconductor package, comprising:
forming reinforcing leads on a base film; and
substantially vertically connecting a portion of the reinforcing leads to four corners of short sides of a semiconductor chip.

15. The method of claim 14, wherein the forming of the reinforcing leads comprises:
coating a conductive material layer on the base film;
forming a photoresist pattern that defines the reinforcing leads on the conductive material layer; and
etching the conductive material layer using the photoresist pattern as an etch mask to form the reinforcing leads.

16. The method of claim 14, wherein the forming of the reinforcing leads comprises:
forming a device hole in the base film for mounting the semiconductor chip;
coating a polymer adhesive layer on the base film;
bonding a conductive material plate to the polymer adhesive layer;
forming a photoresist pattern that defines the reinforcing leads on the polymer adhesive layer; and
etching the conductive material plate using the photoresist pattern as an etch mask, thereby forming the reinforcing leads.

17. The method of claim 14, wherein the connecting of a portion of the reinforcing leads comprises:
forming bonding bumps on the corners of the semiconductor chip;
placing a portion of the reinforcing leads on the bonding bumps; and
applying heat at least greater than about 500° C. with a predetermined compression to the reinforcing leads in a substantially vertical direction to the reinforcing leads.
